(19) United States
(12) Patent Application Publication
(10) Pub. No.: US 2026/0101714 A1
(43) Pub. Date: Apr. 9, 2026

(54) STACKING STRUCTURE AND MANUFACTURING METHOD THEREOF

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW); Yen-Ming Chen, Hsin-Chu County (TW)

(73) Assignee: Taiwan Semiconductor Manufacturing Company, Ltd., Hsinchu (TW)

(21) Appl. No.: 18/892,574

(22) Filed: Sep. 23, 2024

(51) Int. Cl. H01L 23/00; H01L 21/683; H01L 23/31; H01L 23/544; H01L 25/10

(52) U.S. Cl. CPC H10P 72/74; H10W 46/00; H10W 90/00; H10W 46/301; H10W 70/093; H10W 70/60; H10W 70/6528; H10W 74/111; H10W 90/22

(57) ABSTRACT

A stacking structure including a first bonding structure, a first die and a second die is provided. The first die is disposed on a first side of the first bonding structure, and the first die includes a second bonding structure. A first encapsulation material wraps around the first die. The second die is disposed on a second side of the first bonding structure opposite to the first side, and the second die includes a third bonding structure and through die vias. A second encapsulation material wraps around the second die. The second bonding structure of the first die is bonded with the first bonding structure, and the third bonding structure of the second die is bonded with the first bonding structure located between the first and second dies and the first and second encapsulation materials.

### BACKGROUND

Following the trend for high-density integration of various device dies and/or components, three-dimensional integration technologies involving three-dimensional stacking of different devices and components at the wafer levels are developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 are schematic cross-sectional views showing various stages of the manufacturing method for forming a three-dimensional stacking structure according to some embodiments of the present disclosure.

FIG. 10 is a perspective view of an exemplary three-dimensional stacking structure in accordance with some embodiments of the present disclosure.

FIGS. 11-15 are schematic cross-sectional views showing various stages of the manufacturing method for forming a three-dimensional stacking structure according to some embodiments of the present disclosure.

FIG. 16 illustrates a schematic cross-sectional view of an exemplary 3D stacking structure in accordance with some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the three-dimensional (3D) packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

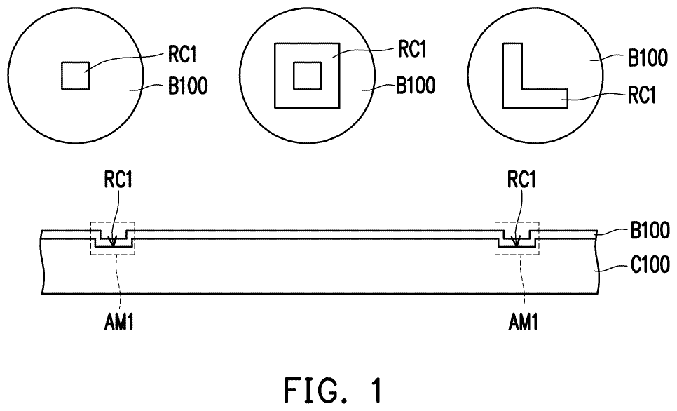

FIGS. 1-9 are schematic cross-sectional views showing various stages of the manufacturing method for forming a three-dimensional stacking structure according to some embodiments of the present disclosure.

In FIG. 1, in some embodiments, a first carrier C100 with recesses RC1 is provided. In some embodiments, the first carrier C100 is or includes a wafer, and the wafer may be a blanket semiconductor wafer (without devices formed therein) of any appropriate size/shape. In some embodiments, the first carrier C100 is a substantially circular dummy wafer formed of a semiconductor material such as bulk silicon. In some embodiments, the recesses RC1 are formed by partially removing the first carrier C100 through performing an etching process (such as dry etching) in combination with photolithographic processes using mask patterns. In some alternative embodiments, the first carrier C100 may be a glass carrier, a ceramic carrier, or any suitable carrier for carrying a reconstructed wafer or stacked structure for the manufacturing method of the die stack structures and/or the packages.

In some embodiments, the multiple recesses RC1 may be formed as recesses or cavities of the same dimensions or of the same geometric shape. In some embodiments, the recesses RC1 may be formed as recesses or cavities of the different dimensions and/or of various geometric shapes. In some embodiments, as seen at the upper part of FIG. 1, some schematic top views of the recesses RC1 are shown, and the recess(es) RC1 may be formed individually as a hollow square hole, a hollow rectangular ring trench or a L-shaped recess. In some embodiments, the recess RC1 is formed with a depth ranging from about 100 nm to about 500 nm. Later, a first dielectric layer B100 is formed over the first carrier C100 covering the recesses RC1. Depending on the depth of the recess RC1 and the thickness of the first dielectric layer B100, the first dielectric layer B100 fills up the recesses RC1, for example. Alternatively, the first dielectric layer B100 is formed conformally covering the recesses RC1 without filling up the recesses RC1. In some embodiments, the material of the first dielectric layer B100 includes silicon oxide, silicon nitride, silicon oxynitride (SiON), or the combinations thereof. In some embodiment, the first dielectric layer B100 may be formed through performing a chemical vapor deposition (CVD) process, such as low-pressure CVD (LPCVD), plasma enhanced CVD (PECVD), and high-density plasma CVD (HDPCVD). In some embodiments, the first dielectric layer B100 is formed of silicon oxynitride with a thickness ranging from about 200 nm to about 800 nm or ranging from about 400 nm to about 600 nm. After the formation of the first dielectric layer B100 covering the recesses RC1, first alignment marks AM1 are formed at the locations of the recesses RC1. Different from the common metallic alignments, the first alignment marks AM1 are non-metallic or dielectric alignment marks constituted by the recesses RC1 and the dielectric material of the first dielectric layer B100 located at the locations of the recesses RC1. In some embodiments, the first alignment marks AM1 are global alignment marks used for wafer level alignment.

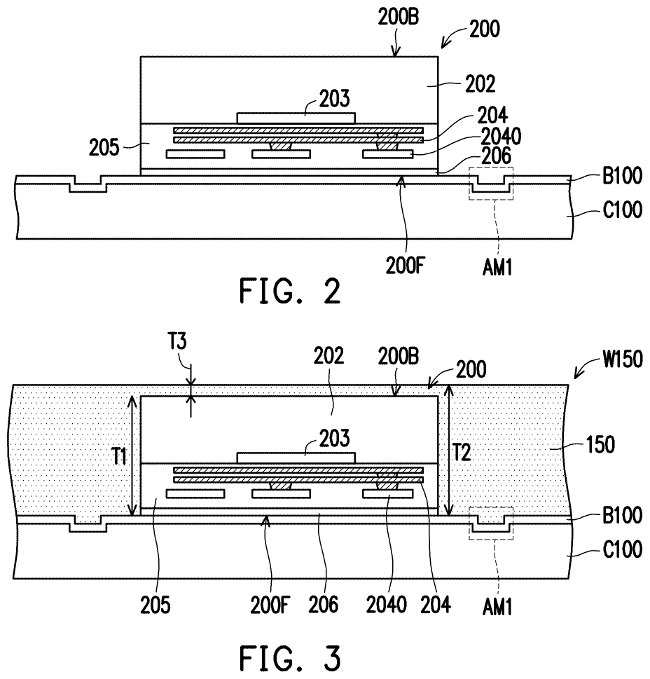

Referring to FIG. 2, at least one first die 200 is provided and disposed on the first dielectric layer B100 over the carrier C100. For example, the first die 200 is placed on the first carrier C100 with its front surface 200F facing the first carrier C100 and its back surface 200B away from the first carrier C100. In FIG. 2, in some embodiments, the first die 200 includes a first semiconductor substrate 202, a first device layer 203 and first metallization structures 204 formed in the first semiconductor substrate 202, and a passivation layer 206 covering the first metallization structures 204 and over the first semiconductor substrate 202. In some embodiments, the first die 200 is a semiconductor die made from a semiconductor wafer (such as a silicon bulk wafer or a silicon-on-insulator (SOI) wafer) or other semiconductor materials, such as groups III-V semiconductor materials. In some embodiments, the first semiconductor substrate 202 includes a bulk semiconductor substrate and/or other type of semiconductor substrate, such as a multi-layered or gradient substrate. In some embodiments, the first semiconductor substrate 202 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, the first device layer 203 includes active devices (e.g., transistors, memories, diodes or the like) and optionally passive devices (e.g., resistors, capacitors, inductors, or the like) formed therein.

As shown in FIG. 2, in certain embodiments, the first metallization structures 204 are embedded within an insulation layer 205 formed on the first semiconductor substrate 202. In some embodiments, the insulation layer 205 includes one or more low-k dielectric layers, and the first metallization structures 204 include multiple metallization layers of interconnect structures. In one embodiment, the interconnect structures include interconnected metal trace lines, vias and contact pads, and the topmost metallization layer of the first metallization structures 204 includes top metal pads 2040. In certain embodiments, the materials of the metallization structures 204 include aluminum (Al), aluminum alloys, copper (Cu), copper alloys, titanium (Ti), nickel (Ni), or combinations thereof.

In exemplary embodiments, some of the devices in the first device layer 203 may be electrically connected with the first metallization structures 204 and some of the devices are electrically interconnected through the first metallization structures 204. The first metallization structures 204 shown herein are merely for illustrative purposes, and the metallization structures 204 may include other configurations and may include one or more through vias and/or damascene structures.

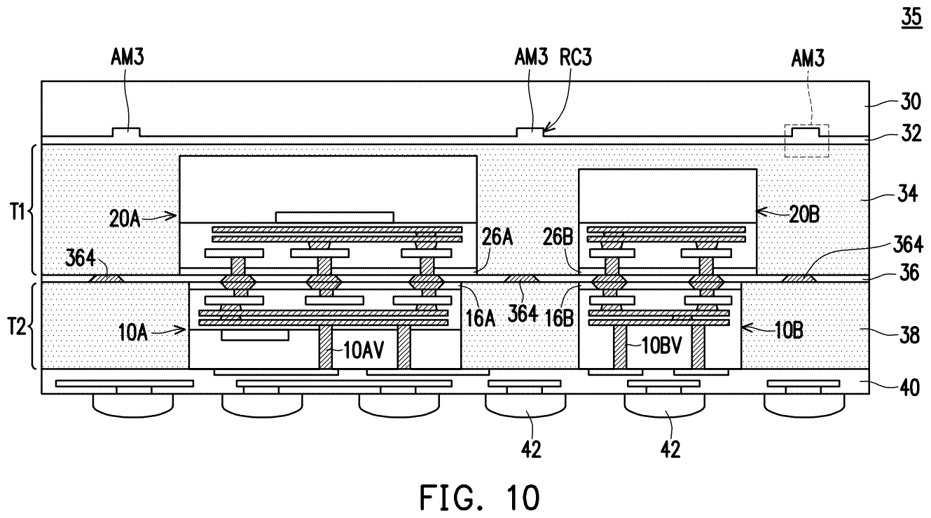

In some embodiments, the material of the passivation layer 206 includes silicon oxide, silicon nitride, undoped silicate glass material or a combination thereof. In some embodiment, the passivation layer 206 may be formed through performing a CVD process, such as sub-atmospheric CVD (SACVD), PECVD, and HDPCVD. For example, the material of the insulation layer 205 is different from that of the passivation layer 206. It is understood that the number of the first dies 200 is merely exemplary, and the first dies 200 may be the same type of dies or different type of dies. In some embodiments, although only one die is shown in FIG. 2, it is understood that a plurality of dies of the same types or different types are provided and packed (FIG. 10). In some embodiments, the first dies 200 are considered as the first tier dies for the reconstructed wafer structure.

In some embodiments, in FIG. 3, an encapsulation material 150 is formed over the first carrier C100 to fully cover the first die(s) 200 to form a reconstructed wafer structure W150. In some embodiments, the first die(s) 200 are fully covered and not revealed from the encapsulation material 150. In some embodiments, the encapsulation material 150 includes an oxide material (such as silicon oxide) or a TEOS-oxide material with better gap filling property using tetraethoxysilane (TEOS) as the source material. In some embodiment, the encapsulation material 150 is formed by performing a CVD process, such as SACVD, LPCVD, PECVD, and HDPCVD. In some embodiments, the encapsulation material 150 includes a resin material such as epoxy resins, phenolic resins, silicon-containing resins, or the like and optionally with or without fillers. In some embodiments, the encapsulation material 150 is formed by a compression molding process. In some embodiments, the encapsulation material 150 is formed by an over-molding process. In some embodiments, a planarization process such as chemical mechanical polishing (CMP) may be optionally performed to planarize the encapsulation material 150 without revealing the first die(s) 200. In FIG. 3, the encapsulation material 150 covers the back surface(s) and sidewalls of the first die(s) 200. For example, the encapsulation material 150 is formed with a thickness T2 larger than the thickness T1 of the first die(s) 200, so that a portion of the encapsulation material 150 covers the back surface 200B of the first die(s) 200, and the portion of the encapsulation material 150 that is located above the back surface 200B has a thickness T3 (larger than zero), where T2 is the sum of T1 and T3 (i.e. T3+T1=T2). It is understood that if different types of dies of various thicknesses are molded by the encapsulation material 150, the encapsulation material 150 fully covers different types of dies without revealing any die from encapsulation material 150.

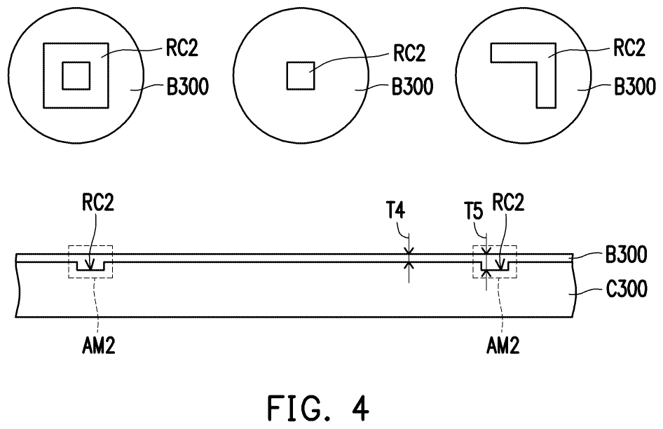

Referring to FIG. 4, in some embodiments, a second carrier C300 is provided with recesses RC2. In some embodiments, the second carrier C300 is or includes a wafer, and the wafer may be a blanket semiconductor dummy wafer (without devices formed therein) of any appropriate size/shape. In some embodiments, the second carrier C300 is a substantially circular dummy wafer formed of a semiconductor material such as bulk silicon. In some embodiments, the recesses RC2 are formed by partially removing the second carrier C300 through performing an etching process (such as dry etching) in combination with photolithographic processes using mask patterns. In some embodiment, the second carrier C300 functions as a support structure and a carrier for carrying a reconstructed wafer or stacked structure for the manufacturing method of the die stack structures and/or the packages.

In some embodiments, the multiple recesses RC2 may be formed as recesses or cavities of the same dimensions or of the same geometric shape. In some embodiments, the recesses RC2 may be formed as recesses or cavities of the different dimensions and/or of various geometric shapes. In some embodiments, as seen at the upper part of FIG. 4, some schematic top views of the recesses RC2 are shown, and the recess(es) RC2 may be formed individually as a hollow rectangular ring trench, a hollow square hole, or a reverse L-shaped recess trench. In some embodiments, the recess RC2 is formed with a depth ranging from about 100 nm to 500 nm. Later, a second dielectric layer B300 is formed over the second carrier C300 covering the recesses RC2. Depending on the depth of the recess RC2 and the thickness of the second dielectric layer B300, the second dielectric layer B300 fills up the recesses RC2, for example. In one embodiment, the second dielectric layer B300 is formed over the second carrier C300 with a thickness T4 and filling up the recesses RC2 with a thickness T5 (larger than T4). In some embodiments, the material of the second dielectric layer B300 includes silicon oxide, silicon nitride, silicon oxynitride (SiON), or the combinations thereof. In some embodiments, the second dielectric layer B300 is formed of silicon oxynitride with a thickness ranging from about 200 nm to about 600 nm. In some embodiments, the material of the second dielectric layer B300 is different from the material of the encapsulation material 150. After the formation of the second dielectric layer B300 covering the recesses RC2, second alignment marks AM2 are formed at the locations of the recesses RC2. In some embodiments, the second alignment marks AM2 are non-metallic or dielectric alignment marks constituted by the recesses RC2 and the dielectric material of the second dielectric layer B300 located at the locations of the recesses RC2. In some embodiments, the second alignment marks AM2 are global alignment marks used for wafer level alignment.

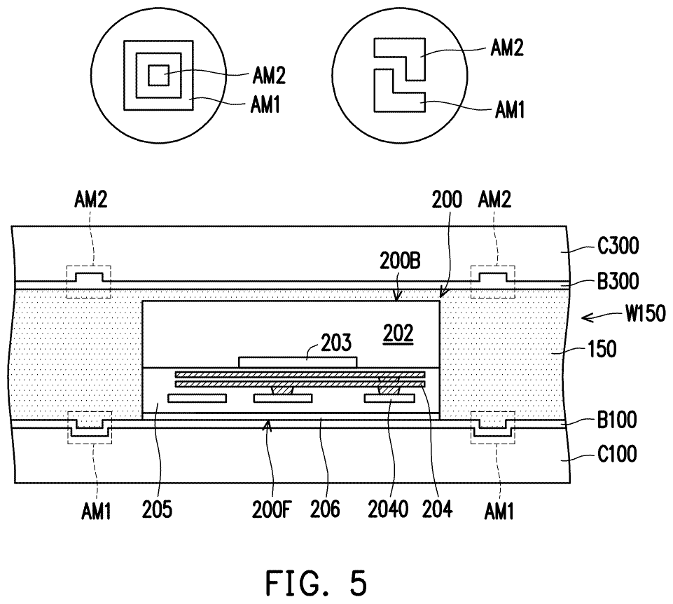

In FIG. 5, the second carrier C300 is disposed on the reconstructed wafer structure W150, and the second dielectric layer B300 is in direct contact with and adheres to the encapsulation material 150. During the placement of the second carrier C300, a global alignment process is performed through the alignment of the alignment marks AM1 and AM2. For example, the second alignment marks AM2 are vertically aligned with the corresponding first alignment marks AM1 for assisting the global alignment. In some embodiments, the patterns of the alignment marks AM1 and AM2 are correspondingly matching patterns. In some embodiments, as shown in the schematic top views of the upper part of FIG. 5, the pattern of the alignment mark AM1 is shaped like an “L”, while the alignment mark AM2 is shaped like a reverse “L”, so that the projections of both alignment marks can be used for accurate alignment and as references for alignment calibration. Similarly, as shown in the schematic top views of the upper part of FIG. 5, the pattern of the alignment mark AM1 is shaped like a square ring, while the alignment mark AM2 has a rectangular shape but smaller in size, so that the projection of the alignment mark AM2 falls within the projection span of the alignment mark AM1 for alignment calibration.

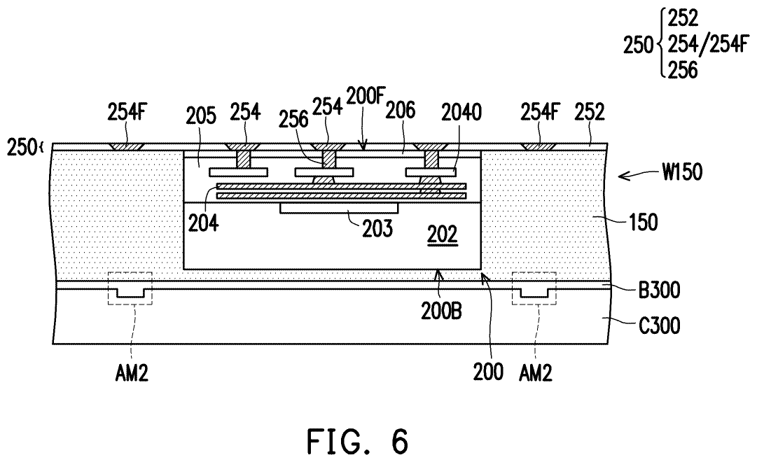

Later, in FIG. 6, the whole stack structure is flipped and then the first carrier C100 is removed, exposing the passivation layer 206 and the encapsulation material 150 upon the removal of the first carrier C100. After removing the first carrier C100, a bonding structure 250 is globally formed over the reconstructed wafer structure W150 and on the passivation layer 206 and the encapsulation material 150. In certain embodiments, the bonding structure 250 includes a bonding dielectric material 252, contact pads 254 embedded in the bonding dielectric material 252 and bonding pad vias 256 penetrating through the passivation layer 206 and connected to the top metal pads 2040. In some embodiments, the material of the bonding dielectric material 252 includes silicon oxide, silicon nitride, undoped silicate glass material or a combination thereof. In some embodiment, the bonding dielectric material 252 may be formed through performing a CVD process, such as SACVD, PECVD, or HDPCVD. In some embodiments, some of the contact pads 254 are connected with the bonding pad vias 256 and are electrically connected with the top metal pads 2040 of the first die 200 so as to electrically connect the first die 200 with the bonding structure 250. In general, most of the contact pads 254 and the bonding pad vias 256 are located within the bonding region for assisting bonding. In some embodiments, the contact pads 254 include electrically floating contact pads 254F located outside the bonding region and may function as alignment marks for the displacement of other dies. In some embodiments, the formation of the bonding structure 250 may involve an alignment process using the alignment marks AM2 as the marks, and the locations of the electrically floating contact pads 254F may correspond to and/or vertically aligned with the locations of the below alignment marks AM2. In some embodiments, the top metal pads 2040 are input/output (I/O) pads or aluminum pads. In exemplary embodiments, the bonding pad vias 256 and the contact pads 254 are formed from the same process and are made of the same metallic material. For example, the metallic material includes Cu, copper alloys, Al, aluminum alloys, titanium (Ti), nickel (Ni), or combinations thereof.

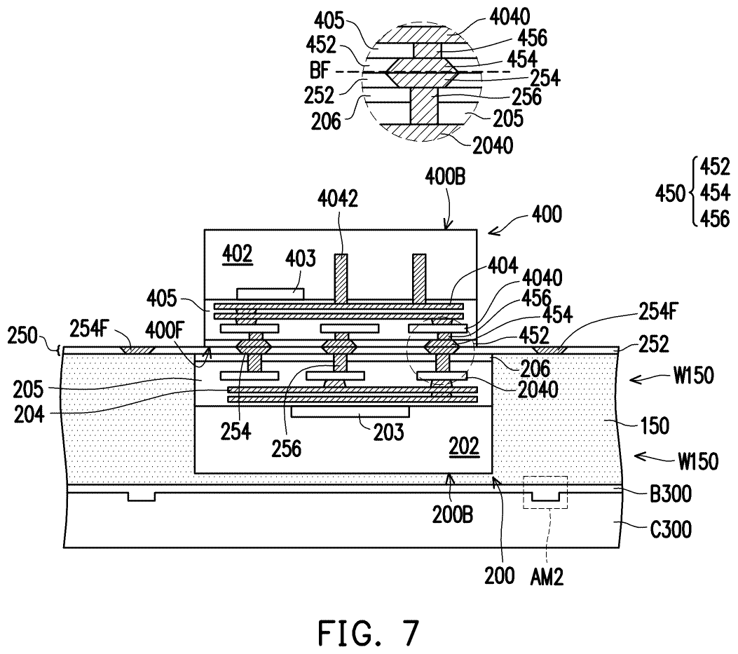

Referring to FIG. 7, in some embodiments, at least one second die 400 is provided and disposed on the bonding structure 250 over the reconstructed wafer structure W150. During the displacement of the dies 400, an alignment process is performed using the electrically floating pads 254F as the alignment marks and/or using the below alignment marks AM2 as the alignment marks. For example, the second die(s) 400 is placed at the predetermined location and on the bonding structure 250 with its front surface 400F facing the bonding structure 250 and its back surface 400B away from the bonding structure 250. In FIG. 7, in some embodiments, the second die 400 includes a second semiconductor substrate 402, a second device layer 403 and second metallization structures 404 formed in the second semiconductor substrate 402, and a second bonding structure 450 over the second metallization structures 404 and the second semiconductor substrate 402. It is understood that multiple dies 400 are included with only one second die(s) 400 is shown as an example, and the multiple second dies 400 may include the same type of dies or different type of dies (FIG. 10). In some embodiments, the second dies 400 are considered as the second tier dies for the reconstructed wafer structure.

In some embodiments, the second die 400 is a semiconductor die made from a semiconductor wafer (such as a silicon bulk wafer or a silicon-on-insulator (SOI) wafer) or other semiconductor materials, such as groups III-V semiconductor materials. In some embodiments, the second semiconductor substrate 402 includes a bulk semiconductor substrate and/or other type of semiconductor substrate, such as a multi-layered or gradient substrate. In some embodiments, the second semiconductor substrate 402 includes elementary semiconductor materials, compound semiconductor materials, or alloy semiconductor materials. In some embodiments, the second device layer 403 includes active devices (e.g., transistors, memories, diodes or the like) and optionally passive devices (e.g., resistors, capacitors, inductors, or the like) formed therein.

As shown in FIG. 7, in certain embodiments, the second metallization structures 404 are embedded within an insulation layer 405 formed on the second semiconductor substrate 402. In some embodiments, the second metallization structures 404 include multiple metallization layers of interconnect structures with metal pads 4040 interconnected with metal trace lines, vias and contact pads. In some embodiments, the metal pads 4040 are input/output (I/O) pads or aluminum pads. In some embodiments, the second metallization structure 404 further includes through substrate vias (TSVs) 4042 embedded within the second semiconductor substrate 402. In certain embodiments, the materials of the metallization structures 404 include Al, aluminum alloys, Cu, copper alloys, Ti, Ni, or combinations thereof.

In exemplary embodiments, some of the devices in the second device layer 403 may be electrically connected with the second metallization structures 404 and some of the devices are electrically interconnected through the second metallization structures 404. The second metallization structures 404 shown herein are merely for illustrative purposes, and the metallization structures 404 may include other configurations and may include one or more through vias and/or damascene structures.

In some embodiments, the bonding structure 450 includes a bonding dielectric material 452, contact pads 454 embedded in the bonding dielectric material 452 and bonding pad vias 456 connected to the metal pads 4040. In some embodiments, the contact pads 454 are connected with the bonding pad vias 456 and are electrically connected with the metal pads 4040 of the second die 400. In some embodiments, the material of the bonding dielectric material 452 includes silicon oxide, silicon nitride, undoped silicate glass material or a combination thereof. In some embodiment, the bonding dielectric material 452 may be formed through performing a CVD process, such as SACVD, PECVD, or HDPCVD. In exemplary embodiments, the bonding pad vias 456 and the contact pads 454 are formed from the same process and are made of the same metallic material, such as Cu, copper alloys, Al, aluminum alloys, Ti, Ni, or combinations thereof.

In FIG. 7, the span of the second die 400 is smaller than the span of the first die 200, and as the bonding structure 250 is a global bonding structure formed over the whole reconstructed wafer structure W150, some of the contact pads 254 are located outside the bonding region between the first and second dies 200 and 400.

In some embodiments, the first die(s) 200 and the second die(s) 400 have different functions. In some embodiments, the first die(s) 200 and the second die(s) 400 have similar functions but different dimensions. In some embodiments, the first die(s) 200 and the second die(s) 400 individually include one or more memory chips such as high bandwidth memory chips, dynamic random access memory (DRAM) chips or static random access memory (SRAM) chips. In some alternative embodiments, the first die(s) 200 and the second die(s) 400 individually include one or more application-specific integrated circuit (ASIC) chips, analog chips, sensor chips, wireless application chips such as Bluetooth chips, radio frequency (RF) chips or voltage regulator chips.

Then, in some embodiments, as shown in FIG. 7, a bonding process is performed to bond the bonding structures 250 and 450 with each other so as to bond the first and second dies 200, 400. In some embodiments, the bonding process includes a two-stage bonding process. In some embodiments, a low temperature heating process at a temperature of about 100° C. to about 200° C. is performed to heat and establish the dielectric-to-dielectric bonding among the bonding dielectric materials 252 and 452 and a high temperature heating process is performed at a temperature of about 200° C. to about 300° C. to heat and establish the metal-to-metal bonding among the metal contact pads 254 and 454. In some embodiments, the first and second dies 200, 400 are bonded and electrically connected through the bonded contact pads 254, 454, the first and second metallization structures 204, 404. Also, it is considered that the first die 200 is bonded to the bonding structure 250 through the connected contact pads 254 and bonding pad vias 256.

After the bonding process, the bonding structure 450 is bonded to the bonding structure 250 and a bonding interface BF (in dash line) exists between the bonding structures 250 and 450. That is, the contact pads 454 are bonded with the contact pads 254, and the bonding dielectric material 452 is bonded with the bonding dielectric material 252. The schematic partial enlarged view of the bonding structures is shown at the upper part of FIG. 7, it is seen that the bonded contact pads 254, 454 are respectively connected to the metal pads 2040, 4040 through the bonding pad vias 256, 456. Through the arrangement of the global bonding structure 250, bonding between the individual dies to the reconstructed wafer can be achieved without forming local bonding structure within the first die 200, which further reduces the total thickness of the stacking structure. In some embodiments, unsymmetrical stacking schemes occur at two opposites of the bonding interface BF, the bonding pad vias 256 penetrate through the passivation layer 206 and extend through the insulation layer 205 to reach the metal pads 2040, while the bonding pad vias 456 extend through the insulation layer 405 to reach the metal pads 4040.

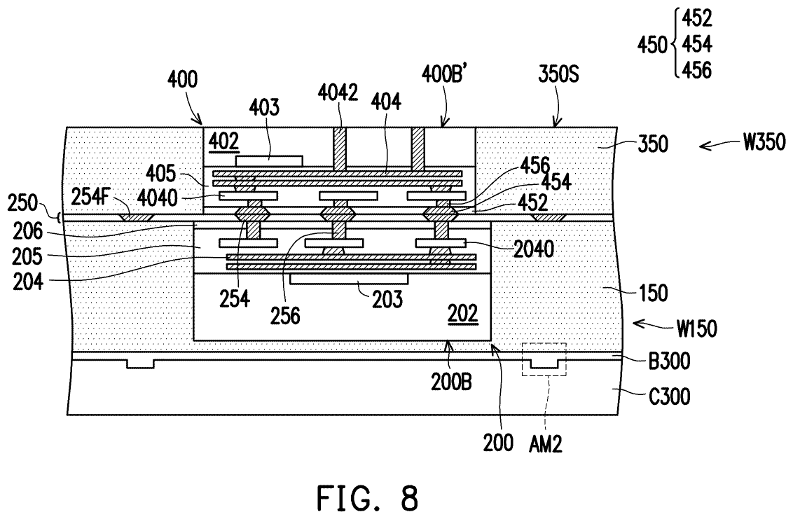

In some embodiments, in FIG. 8, an encapsulation material 350 is formed over the bonding structure 250 to fully cover the second die(s) 400 to form a reconstructed wafer structure W350. In some embodiments, the second die(s) 400 is at least laterally wrapped by the encapsulation material 350. In some embodiments, the encapsulation material 350 includes an oxide material (such as silicon oxide) or a TEOS-oxide material with better gap filling property using tetraethoxysilane (TEOS) as the source material. In some embodiment, the encapsulation material 350 is formed by performing a CVD process, such as SACVD, LPCVD, PECVD, and HDPCVD. In some embodiments, the encapsulation material 350 includes a resin material such as epoxy resins, phenolic resins, silicon-containing resins, or the like and optionally with or without fillers. In some embodiments, the encapsulation material 350 is formed by a compression molding process or by an over-molding process. In some embodiments, a thinning down process and a planarization process are performed to thin down the second die 400 and to planarize the encapsulation material 350 until the TSVs 4042 of the second die(s) 400 are revealed. In some embodiments, the second die 400 may be thinned down to a desirable thickness, removing a portion of the semiconductor substrate 402 from the backside until the TSVs 4042 are exposed. In some embodiments, the thinning down process may include a polishing process, an etching process or a combination thereof. In some embodiments, the planarization process includes one or more CMP processes. After the thinning down process and the planarization process, the treated back surface 400B′ of the thinned second die 400 is coplanar with and levelled with the top surface 350S of the planarized encapsulation material 350. Referring to FIG. 8, the encapsulation material 350 covers the sidewalls of the second die(s) 400 but reveals the back surface(s) 400B′ of the thinned second die(s) 400 and the ends of the TSVs 4042. For example, the encapsulation material 350 is formed with a thickness substantially the same as the thickness of the thinned second die(s) 400.

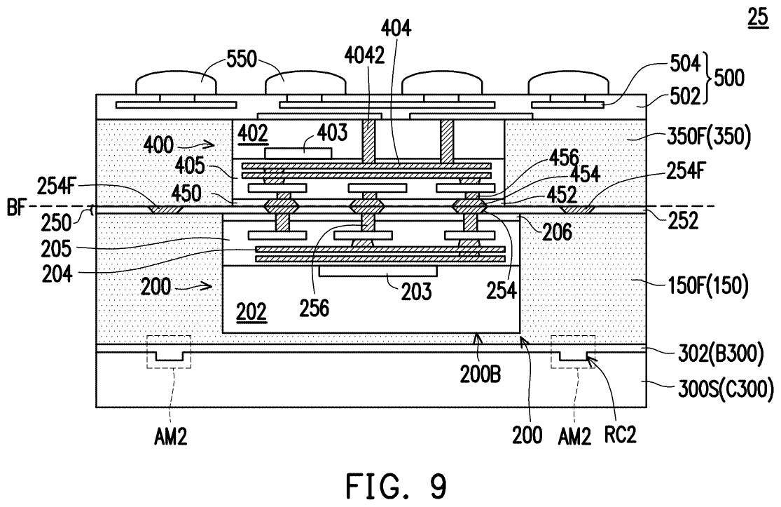

Referring to FIG. 8 and FIG. 9, in some embodiments, a redistribution layer (RDL) 500 is formed over the reconstructed wafer structure W350 covering the second die(s) 400 and the encapsulation material 350. The redistribution layer (RDL) 500 is formed over the whole reconstructed wafer structure W350 and is electrically connected to the below second die(s) 400 through the TSVs 4042 and the metallization structure(s) 404 and further electrically connected to the below first die(s) 200 of the reconstructed wafer structure W150 through the bonding structures 250, 450 and the metallization structure(s) 204. In some embodiments, the RDL 500 includes redistribution patterns 504 embedded in at least one dielectric material layer 502. It is seen that the configurations of the redistribution patterns or the number of layers of the dielectric material layer is not limited by figures herein. The redistribution patterns 504 includes routing patterns, vias and bump pads, for example. In certain embodiments, connectors 550 are formed on the RDL 500. In some embodiments, the material of the dielectric material layer 502 includes silicon oxide, silicon nitride, benzocyclobutene (BCB), epoxy, polyimide (PI), or polybenzoxazole (PBO). In some embodiments, the connectors 550 include conductive bumps (micro bumps or gold bumps), controlled collapse chip connection (C4) bumps, solder balls, ball grid array (BGA) bump, or the like or combinations thereof. In some embodiments, the material of the connectors 550 includes copper, aluminum, lead-free alloys (e.g., gold, silver, aluminum, tin or copper alloys) or lead alloys (e.g., lead-tin alloys). The connectors 550 may be formed by ball mounting process, C4 process, plating process and/or other suitable processes. The connectors 550 are electrically connected to the first and second dies 200, 400 through the RDL 500.

Later, in some embodiments, in FIG. 8 and FIG. 9, after the formation of the RDL 500, a stack structure including the reconstructed wafer structures W350, W150, the support structure C300 and the RDL 500 is obtained. In some embodiments, referring to FIG. 8 and FIG. 9, a singulation process may be performed to cut the stack structure (the reconstructed wafer structures W350, W150, the support C300 and the RDL 500) into individual stacking structures 25. In some embodiments, the singulation process includes a wafer dicing process or a sawing process, cutting through the second carrier C300, the dielectric layer B300, the reconstructed wafer structure W350 and the RDL 500. During the singulation process, the dicing or sawing process does not cut into the alignment marks AM2 or the electrically floating contact pads 254F.

Referring to FIG. 9, each stacking structure 25 includes a support 300S (a portion of the second carrier C300), at least one first die 200 encapsulated by the first encapsulant 150F (a portion of the encapsulation material 150), an auxiliary dielectric layer 302 disposed between the first encapsulant 150F and the support 300S, the bonding structure 250 disposed on the first encapsulant 150F and on the first die 200, at least one second die 400 disposed on the bonding structure 250 and laterally wrapped by the second encapsulant 350F (a portion of the encapsulation material 350), the RDL 500 disposed on the second die 400 and the second encapsulant 350F, and the connectors 550 disposed on the RDL 500. In some embodiments, within the stacking structure 25, the bonding structure 250 is bonded with the bonding structure 450 of the second die 400, while the first die 200 is electrically connected with the second die 400 through the bonding structure 250 connected to the first die 200. In some embodiments, for the stacking structure 25, the auxiliary dielectric layer 302 includes the non-metallic dielectric alignment marks AM2 formed at locations beside the first and second dies 200, 400 and in the recesses RC2 of the support 300S. Also, in the stacking structure 25, the bonding structure 250 includes electrically floating metallic alignment marks 254F at locations beside the first and second dies 200, 400 and right above the alignment marks AM2.

In some embodiments, through the formation of the non-metallic alignment marks AM1/AM2, accurate alignment is achieved, and a more compact stacking structure with a reduced height (thickness) is obtained as there is no need to form a thicker dielectric layer and devoid of using metal/metallic alignment marks. Further, through the globally formed bonding structure, reliable bonding is established through bonding structures with shorter connection path(s). Further, the alignment mark(s) embedded in the bonding structure aims to further improves the alignment, and the yield and reliability of the 3D stacking structure(s) 25 are improved.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure.

FIG. 10 is a perspective view of an exemplary three-dimensional stacking structure in accordance with some embodiments of the present disclosure. The stacking structure may be formed through the similar manufacturing processes as described above, except for multiple and different types of individual dies are provided. In some embodiments, multiple dies 20A and multiple dies 20B are provided as first tier dies to form a reconstructed wafer or panel structure, and later multiples dies 10A and multiple dies 10B are provided as the second tier dies and are stacked and bonded onto the bonding structure 36 to form a two-tiered reconstructed wafer or panel structure. The majority of the manufacturing processes are similar or the same as those described in the previous paragraphs, and details will not be repeated herein.

Referring to FIG. 10, in some embodiments, the stacking structure 35 includes a redistribution layer (RDL) 40 with connectors 42 disposed on and below the RDL 40, a lower tier structure T2 including at least one die 10A and at least one die 10B laterally wrapping by the encapsulant 38, a bonding structure 36 disposed on the lower tier structure T2, an upper tier structure T1 including at least one die 20A and at least one die 20B encapsulated by the encapsulant 34, an auxiliary dielectric layer 32 disposed on the upper tier structure T1, and a support 30 located on the auxiliary dielectric layer 32. In some embodiments, the dies 10A and 10B are electrically connected with the below RDL 40 through TSVs 10AV and 10BV respectively.

For example, the support 30 is similar to or the same as the support 300S mentioned above, and similar materials and formation methods may be used for the support 30. Similarly, the encapsulant 34 or 38 is similar to or the same as the encapsulant 150F, 350F, the bonding structures 16A, 16B are similar to the bonding structures 450, the bonding structure 36 is similar to the bonding structure 250, the bonding films 26A, 26B are similar to the passivation layer 206, the auxiliary dielectric layer 32 is similar to or the same as the auxiliary dielectric layer 302, the RDL 40 and the connectors 42 are similar to or the same as the RDL 500 and the connectors 550 respectively, so that the same or similar materials and formation methods may be used. Detailed descriptions are skipped for simplification.

Referring to FIG. 10, the bonding structures 16A, 16B of the dies 10A, 10B are bonded with the bonding structure 36, and the dies 20A, 20B are connected with the bonding structure 36. Through the arrangement of the global bonding structure 36, fusion bonding exists between the bonding films 26A, 26B of the individual dies 20A, 20B with the global bonding structure 36 but the dies 20A, 20B are provided without forming local bonding structure therein.

In some embodiments, in FIG. 10, separate dies 20A and 20B of different thicknesses are arranged side-by-side on the bonding structure 36, and the encapsulant 34 encloses and fully covers the dies 20A and 20B (covering the sidewalls and the back surfaces of the dies 20A and 20B). From FIG. 10, for the thinner die 20B, it is seen a larger distance existing between the back surface of the die 20B and the auxiliary dielectric layer 32, when compared with the smaller distance existing between the back surface of the die 20A and the auxiliary dielectric layer 32.

In some embodiments, within the stacking structure 35, the non-metallic alignment marks AM3 are formed at the recesses RC3 of the support 30 at locations beside and between the dies 20A, 20B, 10A, and 10B. Also, in the stacking structure 35, the bonding structure 36 includes electrically floating metallic marks 364 at locations beside and between the dies 20A, 20B, 10A, and 10B and right above the alignment marks AM3.

It is understood that the number of the dies 10A, 10B, 20A, 20B may be one, two or more than two, but the disclosure is not limited thereto. In some embodiments, the dies 20A/20B and the dies 10A/10B have different functions. In some embodiments, the dies 20A/20B and the dies 10A/10B have the same or similar functions. In some embodiments, the die 20A or 20B includes a memory chip such as a high bandwidth memory chip, a dynamic random access memory (DRAM) chip or a static random access memory (SRAM) chip. In some alternative embodiments, the dies 10A or 10B includes an application-specific integrated circuit (ASIC) chip, an analog chip, a sensor chip, a wireless application chip such as a Bluetooth chip, a radio frequency (RF) chip or a voltage regulator chip. In one embodiment, the die 20A or 20B includes a memory chip, and the die 10A or 10B includes an ASIC chip. Although not expressly shown in FIG. 10, some of the conductive features of the dies 20A, 20B, 10A, and 10B are electrically interconnected to one another so that the dies 20A, 20B, 10A, and 10B are electrically connected.

As the 3D stacking structure 25 or 35 includes multiple dies stacked on one another and face-to-face connected with one another through global bonding structure, the stacked dies are integrated in a compact form. In some embodiments, the 3D stacking structure 25, 35 may be considered as an integrated circuit (IC) die or a system-on-integrated-chip (SoIC) die.

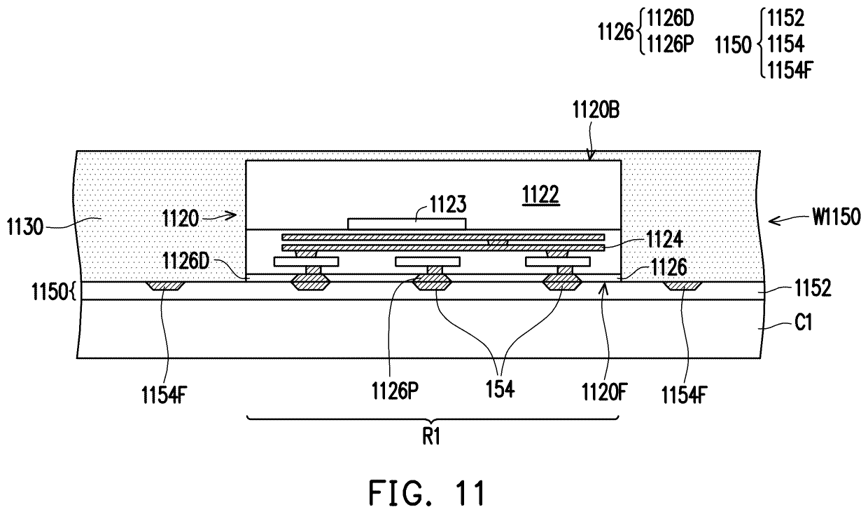

FIGS. 11-15 are schematic cross-sectional views showing various stages of the manufacturing method for forming a three-dimensional stacking structure according to some embodiments of the present disclosure.

Referring to FIG. 11, a bonding structure 1150 is formed on a carrier C1. In some embodiments, the carrier C1 is a sacrificial carrier, such as a dummy wafer. In one embodiment, the carrier C1 includes a blank semiconductor material substrate. In some embodiments, the carrier C is a glass substrate, a metal plate, a plastic supporting board or the like, but other suitable substrate materials may be used as long as the materials are compatible with the subsequent steps of the process. In some embodiments, the bonding structure 1150 includes a bonding dielectric material 1152 and bonding pads 1154 embedded in the bonding dielectric material 1152. As seen in FIG. 11, the bonding dielectric material 1152 is formed with a thickness larger than those of the bonding pads 1154, so that the bottoms of the bonding pads 1154 are fully covered by the bonding dielectric material 1152. The materials and formation methods for forming the bonding structure 1150 are similar to those of the bonding structure 250 or 450.

Later, referring to FIG. 11, in some embodiments, at least one die 1120 is provided and disposed onto the bonding structure 1150. In some embodiments, an alignment process is performed firstly using the electrically floating marks 1154F as the alignment marks. In some embodiments, after the alignment process, the die(s) 1120 is disposed at the predetermined location and on the bonding structure 1150. In some embodiments, the die(s) 1120 is disposed on the bonding structure 1150 with its front surface 1120F facing the bonding structure 1150 and its back surface 1120B away from the bonding structure 1150. In FIG. 11, in some embodiments, the die 1120 includes a substrate 1122, a device layer 1123 and metallization structures 1124 formed on the substrate 1122, and a bonding structure 1126 over the metallization structures 1124 and the substrate 1122. In embodiments, the bonding structure 1126 includes a bonding dielectric material 1126D and bonding pads 1126P embedded in the bonding dielectric material 1126D, and the bonding pads 1126P are connected with the metallization structure 1124. Later, a bonding process is performed to bond the bonding structures 1126 and 1150 with each other so as to bond the die(s) 1120 with the bonding structure 1150. In some embodiments, through the bonding process, the dielectric-to-dielectric bonding is established between the bonding dielectric materials 1126D and 1152, and the metallic-to-metallic bonding is established between the metallic bonding pads 1126P and 1154. As seen in FIG. 11, the bonding structure 1150 includes some electrically floating marks 1154F located outside of the bonding region R1 of the die 1120 to the bonding structure 1150. For example, the electrically floating marks 1154F located outside the bonding region may function as alignment marks for the displacement of other dies.

In some embodiments, in FIG. 11, an encapsulation material 1130 is formed on the bonding structure 1150 and over the carrier C1 to fully cover the die(s) 1120 to form a reconstructed wafer structure W1150. In some embodiments, the die(s) 1120 are fully covered and not revealed from the encapsulation material 1130. In some embodiments, the encapsulation material 1130 includes an oxide material (such as TEOS-oxide material). In some embodiment, the encapsulation material 1130 is formed by performing a CVD process, such as SACVD, LPCVD, PECVD, and HDPCVD. In some embodiments, a planarization process such as chemical mechanical polishing (CMP) may be optionally performed to planarize the encapsulation material 1130 without revealing the die(s) 1120.

In FIG. 11, the encapsulation material 1130 covers the back surface(s) 1120B and sidewalls of the die(s) 1120. For example, the encapsulation material 1130 is formed with a thickness larger than the thickness of the die(s) 1120, so that a portion of the encapsulation material 1130 remains on and covers the back surface 1120B of the die(s) 1120. It is understood that if different types of dies of various thicknesses are covered by the encapsulation material, the encapsulation material fully covers different types of dies without revealing any die from encapsulation material.

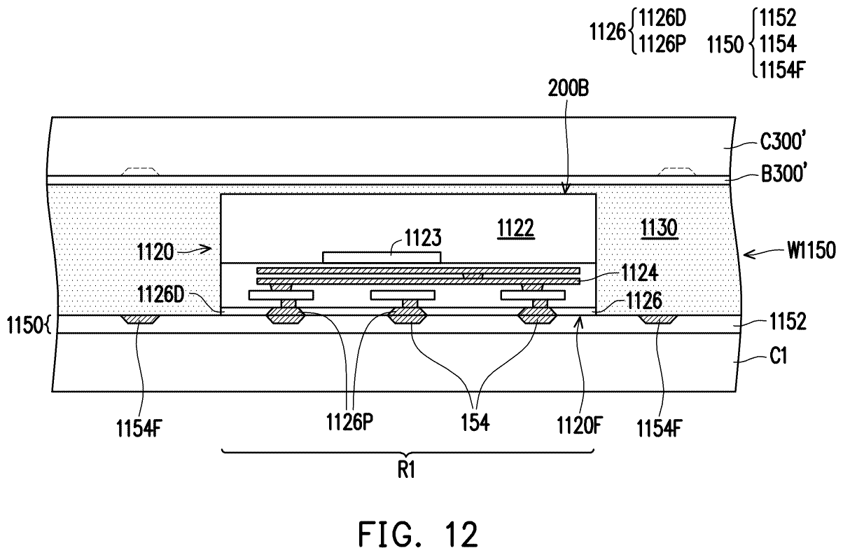

Referring to FIG. 12, in some embodiments, another carrier C300′ is provided with the dielectric layer B300′ located between the carrier C300′ and the reconstructed wafer structure W1150. In some embodiments, the carrier C300′ is formed with recesses (shown in dotted lines) and along with the alignment marks similar to those in the carrier C300. In some embodiments, the carrier C300′ is formed without recesses. In some embodiments, the carrier C300′ and the dielectric layer B300′ are similar to the second carrier C300 and the dielectric layer B300, and the same or similar materials and formation methods may be used. In some embodiments, the carrier C300′ functions as a support structure of the stacking structure for the manufacturing method of the die stack structures and/or the packages.

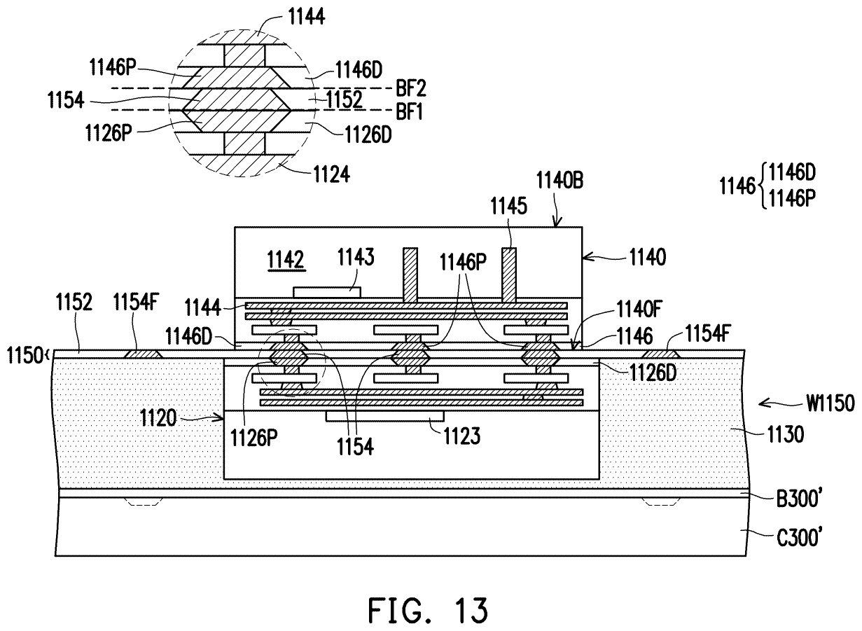

In some embodiments, referring to FIG. 13, the whole stack structure is flipped and the carrier C1 is removed. After the removal of the carrier C1, an etching process is performed to the exposed bonding structure 1150, partially removing the bonding dielectric material 1152 until the bonding pads 1154 are exposed.

Later, referring to FIG. 13, in some embodiments, at least one die 1140 is provided and disposed onto the bonding structure 1150. During the displacement of the dies 1140, an alignment process is performed firstly using the electrically floating marks 1154F as the alignment marks. In some embodiments, after the alignment process, the die(s) 1140 is disposed at the predetermined location and on the bonding structure 1150 with its front surface 1140F facing the bonding structure 1150 and its back surface 1140B away from the bonding structure 1150. In FIG. 13, in some embodiments, the die 1140 includes a substrate 1142, a device layer 1143, through substrate vias (TSVs) 1145, and metallization structures 1144 formed on the substrate 1142, and a bonding structure 1146 over the metallization structures 1144 and the substrate 1142. In embodiments, the bonding structure 1146 includes a bonding dielectric material 1146D and bonding pads 1146P embedded in the bonding dielectric material 1146D, and the bonding pads 1146P are connected with the metallization structure 1144. Later, a bonding process is performed, the bonding structures 1146 and 1150 are bonded with each other so as to bond the die(s) 1140 to the bonding structure 1150. In some embodiments, through the bonding process, the dielectric-to-dielectric bonding is established between the bonding dielectric materials 1146D and 1152, and the metallic-to-metallic bonding is established between the metallic bonding pads 1146P and 1154. In FIG. 13, through the bonding structure, the dies 1120 and 1140 are bonded to the bonding structure 1150 and are bonded together through the bonded bonding pads 1126P, 1154 and 1146P, achieving a triple stacking bonding scheme.

After the bonding process, the bonding structure 1146 is bonded to the bonding structure 1150 and a bonding interface BF2 (in dash line) exists between the bonding structures 1146 and 1150, and the bonding structure 1126 is bonded to the bonding structure 1150 and a bonding interface BF1 (in dash line) exists between the bonding structures 1126 and 1150. As seen the schematic partial enlarged view at the upper part of FIG. 13, the bonding pads 1146P and 1126P are both bonded with the bonding pads 1154 located in-between, and the bonding dielectric materials 1146D and 1126D located at opposite sides of the bonding dielectric material 1152 are bonded with the bonding dielectric material 1152. In the schematic partial enlarged view of the bonding structures is shown at the upper part of FIG. 13, it is seen that the three bonding pads 1146P, 1154 and 1126P as well as three dielectric layers of dielectric bonding materials 1146D, 1152 and 1126D are stacked upon and bonded with each other with two bonding interfaces BF1 and BF2 there-between. Through the arrangement of the global bonding structure 1150, strong and reliable bonding between the individual dies within the reconstructed wafers can be achieved.

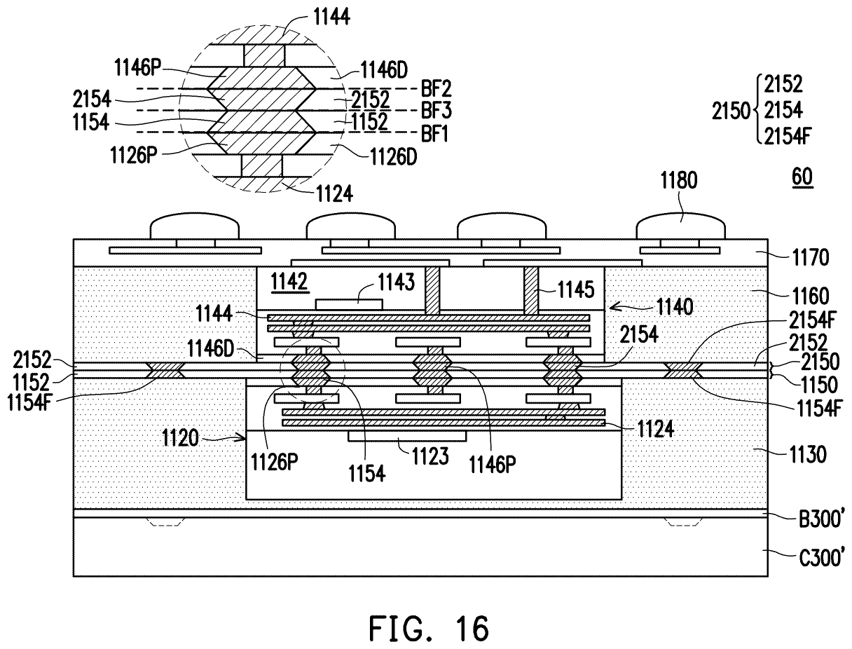

In some alternative embodiments, following the removal of the carrier C1 and performing the etching process to partially remove the bonding dielectric material 1152 until the bonding pads 1154 are exposed, another bonding structure 2150 (in FIG. 16) is formed directly on the exposed bonding structure 1150, and after the formation of the bonding structure 2150, the dies 1140 are aligned and placed on the predetermined location of the bonding structure 2150. Similarly, through performing one or more bonding processes, the bonding structure 1146 is bonded to the bonding structure 2150, the bonding structure 2150 is bonded with the bonding structure 1150, and the bonding structure 1150 is bonded with the bonding structure 1126, thus the dies 1120 and 1140 are bonded and electrically connected. Hence, as seen the schematic partial enlarged view at the upper part of FIG. 16, there are a bonding interface BF2 (in dash line) existing between the bonding structures 1146 and 2150, a bonding interface BF3 (in dash line) existing between the bonding structures 2150 and 1150, and a bonding interface BF1 (in dash line) existing between the bonding structures 1126 and 1150.

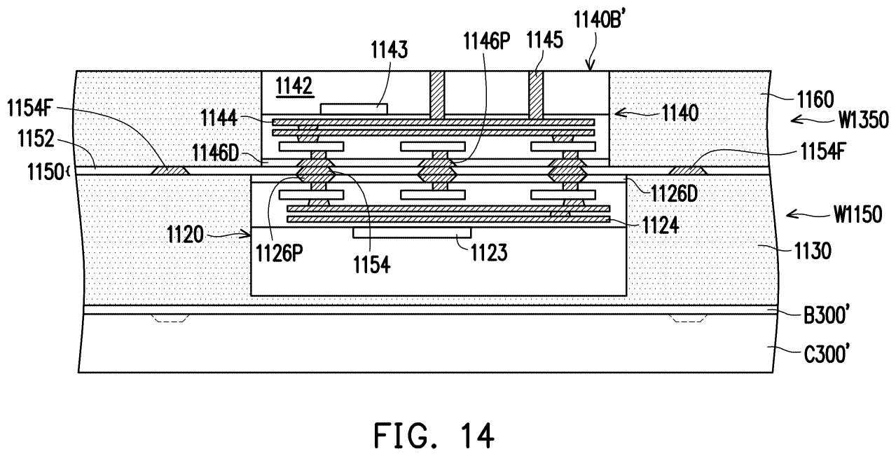

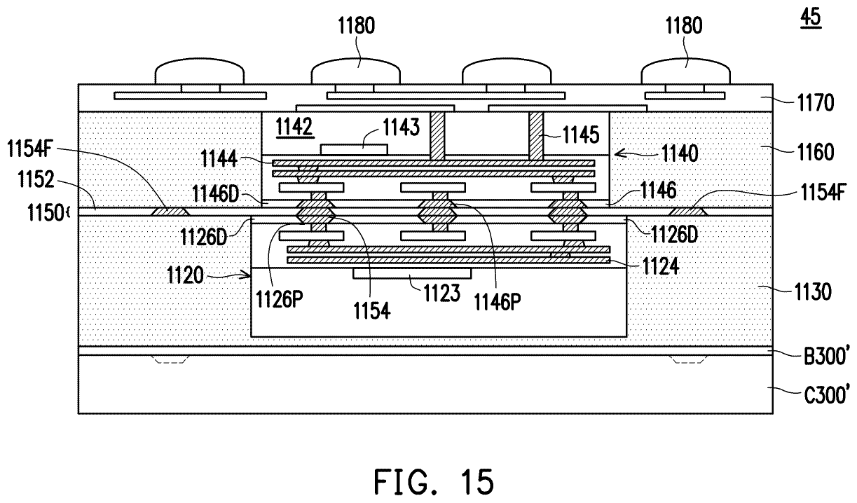

Referring to FIG. 14, an encapsulation material 1160 is formed over the bonding structure 1150 to fully cover the die(s) 1140 to form a reconstructed wafer structure W1350. In some embodiments, the die(s) 1140 is at least laterally wrapped by the encapsulation material 1160. In some embodiments, the encapsulation material 1160 includes an oxide material (such as silicon oxide) or a TEOS-oxide material with better gap filling property using tetraethoxysilane (TEOS) as the source material formed by CVD. In some embodiments, the encapsulation material 1160 includes a resin material such as epoxy resins, phenolic resins, silicon-containing resins, or the like and optionally with or without fillers formed by a molding process. In some embodiments, a thinning down process and a planarization process are performed to thin down the die 1140 and to planarize the encapsulation material 1160 until the TSVs 1145 of the die(s) 1140 are revealed. In some embodiments, the thinning down process and the planarization are similar to those described previously and shall not be repeated herein. After the thinning down process and the planarization process, the back surface 1140B′ of the thinned die 1140 is coplanar with and levelled with the top surface of the planarized encapsulation material 1160. Referring to FIG. 14, the encapsulation material 1160 covers the sidewalls of the die(s) 1140 but reveals the back surface(s) 1140B′ of the thinned die(s) 1140 and the ends of the TSVs 1145. For example, the thickness of the encapsulation material 1160 is substantially the same as the thickness of the thinned die(s) 1140.

In FIG. 14 and FIG. 15, in some embodiments, a redistribution layer (RDL) 1170 is formed over the reconstructed wafer structure W1350 covering the die(s) 1140 and the encapsulation material 1160. The redistribution layer (RDL) 1170 is formed over the whole reconstructed wafer structure W1350 and is electrically connected to the below die(s) 1140 through the TSVs 1145 and the metallization structure(s) 1144 and further electrically connected to the below die(s) 1120 of the reconstructed wafer structure W1150 through the bonding structures 1146, 1150, 1126 and the metallization structure(s) 1124. In some embodiments, the RDL 1170 includes redistribution patterns embedded in a dielectric material, and the configurations of the redistribution patterns or the number of layers of the dielectric material is not limited by figures herein. In certain embodiments, connectors 1180 are formed on the RDL 1170. The materials and formation of the RDL 1170 and the connectors 1180 are similar to the RDL and the connectors described above, and the details will be skipped herein. The connectors 1180 are electrically connected to the dies 1120, 1140 through the RDL 1170.

Later, in some embodiments, referring to FIG. 14 and FIG. 15, after the formation of the RDL 1170 and the connectors 1180, a singulation process may be performed to cut the stack structure (the reconstructed wafer structures W1350, W1150, the support C300′ and the RDL 1170) into individual stacking structures 45. In some embodiments, the singulation process includes a wafer dicing process or a sawing process, referring to FIG. 14 and FIG. 15, cutting through the RDL 1170, the reconstructed wafer structure W1350 and cutting through the carrier C300′ along with the dielectric layer B300′ thereon. During the singulation process, the dicing or sawing process does not cut into the electrically floating marks 1154F.

Referring to FIG. 15, each stacking structure 45 includes a support C300′, a dielectric layer B300′, at least one die 1120 encapsulated by the encapsulation material 1130 (a portion of the encapsulation material 1130), the bonding structure 1150 disposed on the die 1120 and the encapsulation material 1130, at least one die 1140 disposed on the bonding structure 1150 and laterally wrapped by the encapsulation material 1160 (a portion of the encapsulation material 1160), the RDL 1170 disposed on the die 1140 and the encapsulation material 1160, and the connectors 1180 disposed on the RDL 1170. In some embodiments, within the stacking structure 45, the bonding structure 1150 is bonded with the bonding structures 1146 and 1126 of the dies 1140 and 1120 respectively, and the dies 1120 and 1140 are electrically connected through the bonding structures 1126, 1150 and 1146. Within the stacking structure 45, the bonding structure 1150 includes electrically floating marks 1154F at locations beside the bonded dies 1120, 1140. In some embodiments, for the stacking structure 45, if the support C300′ is provided with non-metallic alignment marks as described previously, the locations of the electrically floating marks 1154F may correspond to and vertically aligned with the non-metallic dielectric alignment marks.

FIG. 16 illustrates a schematic cross-sectional view of an exemplary 3D stacking structure in accordance with some embodiments of the present disclosure. As mentioned above, the fabrication of the exemplary structure shown in FIG. 16 may follow the manufacturing processes as described from FIG. 11 to FIG. 15, except for forming an additional bonding structure 2150 before placing the dies 1140.

In FIG. 16, the 3D stacking structure 60 includes at the support C300′, the dielectric layer B300′, at least one die 1120 encapsulated by the encapsulation material 1130 (a portion of the encapsulation material 1130), the bonding structures 2150 and 1150 disposed on the die 1120 and the encapsulation material 1130, at least one die 1140 disposed on the bonding structure 2150 and laterally wrapped by the encapsulation material 1160 (a portion of the encapsulation material 1160), the RDL 1170 disposed on the die 1140 and the encapsulation material 1160, and the connectors 1180 disposed on the RDL 1170. In some embodiments, within the stacking structure 60, the additional bonding structure 2150 is bonded with the bonding structure 1150, and the bonding structures 1146 and 1126 of the dies 1140 and 1120 respectively bonded to the bonding structures 2150 and 1150, and the dies 1120 and 1140 are electrically connected through the bonding structures 1126, 1150, 2150 and 1146. Compared with the 3D stacking structure 45, the main structural difference of the 3D stacking structure 60 lies in that the additional global bonding structure 2150 is formed between the bonding structure 1150 and the die 1140 and the laterally wrapping encapsulation material 1160. In some embodiments, the materials of the bonding structure 2150 are similar to those of the bonding structure 1150. In some embodiments, the material of the bonding dielectric material 2152 is different from the material of the bonding dielectric material 1152. Except for the similar manufacturing processes as described above, the bonding structure 2150 is formed as a global bonding structure over the reconstructed wafer structure and formed directly on the bonding structure 1150. In some embodiments, the bonding structure 2150 is formed with the bonding pads 2154 exposed from the bonding dielectric material 2152, and etching or planarization is optional. The other following manufacturing processes are similar or the same as those described in the previous embodiments, and details are skipped herein.

As seen the schematic partial enlarged view at the upper part of FIG. 16, the bonding pads 1146P and 1126P are respectively bonded to the bonding pads 2154 and 1154 located in-between, and the bonding pads 1154 and 2154 are bonded with each other. Also, the bonding dielectric materials 1146D and 1126D located at opposite sides of the stack of the bonding dielectric materials 2152 and 1152 are respectively bonded with the bonding dielectric materials 2152 and 1152. In the schematic partial enlarged view of the bonding structures is shown at the upper part of FIG. 16, it is seen that the four bonding pads 1146P, 2154, 1154 and 1126P as well as four dielectric layers of dielectric bonding materials 1146D, 2152, 1152 and 1126D are stacked upon and bonded with each other with three bonding interfaces BF1, BF3 and BF2 there-between, thus achieving quadruple stacking bonding scheme.

In exemplary embodiments, the 3D stacking structures 25, 35, 45, 60 as described above may be additional processed in the subsequent processes to be connected with further connection structures before dicing, and these subsequent processes may be modified based on the product design and will not be described in details herein.

In exemplary embodiments, a global bonding structure is formed with alignment marks embedded therein for assisting die placement, a thinner sacrificial carrier may be used for better thermal dissipation as less or no alignment marks are needed for the sacrificial carrier. Also, through the arrangement of one or more global bonding structures, accurate alignment and reliable bonding can be established at the same time, so that the production yield and reliability are significantly enhanced.

In some embodiments of the present disclosure, a stacking structure including a support structure, a first die and a second die is provided. The support structure has a first surface and a second surface opposite to the first surface, and a dielectric layer on the first surface. The support structure includes a recess concave from the first surface and filled with the dielectric layer, and a non-metallic alignment mark located at the recess. The first die is disposed over the support structure and encapsulated by a first encapsulant. A portion of the first encapsulant is located between the first die and the support structure. The second die is disposed on the first bonding structure and encapsulated by a second encapsulant. The second die includes a second bonding structure and through die vias. The first die and the second die are located at opposite sides of the first bonding structure. The first bonding structure is bonded with the first die and bonded with the second bonding structure of the second die so that the first and second dies are electrically connected.

In some embodiments of the present disclosure, a stacking structure including a first bonding structure, a first die and a second die is provided. The first die is disposed on a first side of the first bonding structure, and the first die includes a second bonding structure. A first encapsulation material wraps around the first die. The second die is disposed on a second side of the fir A stacking structure including a first bonding structure, a first die and a second die is provided. The first die is disposed on a first side of the first bonding structure, and the first die includes a second bonding structure. A first encapsulation material wraps around the first die. The second die is disposed on a second side of the first bonding structure opposite to the first side, and the second die includes a third bonding structure and through die vias. A second encapsulation material wraps around the second die. The second bonding structure of the first die is bonded with the first bonding structure, and the third bonding structure of the second die is bonded with the first bonding structure located between the first and second dies and the first and second encapsulation materials. st bonding structure opposite to the first side, and the second die includes a third bonding structure and through die vias. A second encapsulation material wraps around the second die. The second bonding structure of the first die is bonded with the first bonding structure, and the third bonding structure of the second die is bonded with the first bonding structure located between the first and second dies and the first and second encapsulation materials.

In some embodiments of the present disclosure, a method for forming a stacking structure is described. A first bonding structure with electrically floating marks is formed. First dies are provided, and each first die has a second bonding structure. The first dies are disposed and aligned over a first side of the first bonding structure using the electrically floating marks as alignment marks. The first dies are bonded with the first bonding structure, and each second bonding structure is bonded with the first bonding structure. A first encapsulation material is formed over the first dies and covers the first die to form a first wafer structure. Second dies are provided, and each second die has a third bonding structure. The second dies are disposed and aligned over a second side of the first bonding structure opposite to the first side using the electrically floating marks as the alignment marks. The second dies are bonded with the first bonding structure, and each third bonding structure is bonded with the first bonding structure. A second encapsulation material is formed over the second dies and at least laterally wraps around the second dies to form a second wafer structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a support structure, having a first surface and a second surface opposite to the first surface and a dielectric layer on the first surface, wherein the support structure includes a recess concave from the first surface and filled with the dielectric layer, and a non-metallic alignment mark located at the recess;
a first die, disposed over the support structure and encapsulated by a first encapsulant, wherein a portion of the first encapsulant is located between the first die and the support structure;
a first bonding structure disposed on the first encapsulant and the first die; and
a second die, disposed on the first bonding structure and encapsulated by a second encapsulant, wherein the second die includes a second bonding structure and through die vias, wherein the first die and the second die are located at opposite sides of the first bonding structure, and the first bonding structure is bonded with the first die and bonded with the second bonding structure of the second die so that the first and second dies are electrically connected.

2. The structure of claim 1, wherein the support structure includes a semiconductor material.

3. The structure of claim 1, wherein a material of the dielectric layer is different from a material of the first encapsulant.

4. The structure of claim 1, wherein the first bonding structure includes a first bonding dielectric material and first bonding pads embedded in the first bonding dielectric material.

5. The structure of claim 4, wherein the first die comprises a passivation layer in contact with the first bonding dielectric material, and first metallization structures therein, and bonding pad vias are located between the first bonding pads of the first bonding structure and the first metallization structure.

6. The structure of claim 4, wherein the second bonding structure includes a second bonding dielectric material and second bonding pads embedded in the second bonding dielectric material, and a bonding interface is located between the first bonding structure and the second bonding structure.

7. The structure of claim 1, wherein the first bonding structure includes electrically floating pads located beside a bonding region between the first bonding structure and the first and the second dies.

8. The structure of claim 1, further comprising a redistribution layer located on the second die and the second encapsulant and electrically connected with the through die vias of the second die.

9. The structure of claim 1, wherein the non-metallic alignment mark includes a dielectric alignment mark made of a dielectric material of the dielectric layer.

10. A structure, comprising:
a first bonding structure;
a first die disposed on a first side of the first bonding structure, wherein the first die includes a second bonding structure;
a first encapsulation material wrapping around the first die;
a second die disposed on a second side of the first bonding structure opposite to the first side, wherein the second die includes a third bonding structure and through die vias; and
a second encapsulation material wrapping around the second die,
wherein the second bonding structure of the first die is bonded with the first bonding structure, and the third bonding structure of the second die is bonded with the first bonding structure located between the first and second dies and the first and second encapsulation materials.

11. The structure of claim 10, wherein the first bonding structure includes electrically floating marks located beside a bonding region between the first bonding structure and the first and the second dies.

12. The structure of claim 10, further comprising a redistribution layer located on the second die and the second encapsulant and electrically connected with the through die vias of the second die.

13. The structure of claim 10, wherein the first bonding structure includes a first bonding dielectric layer and first bonding pads embedded therein, the second bonding structure includes a second bonding dielectric layer and second bonding pads embedded therein, and a first interface is located between the bonded first and second bonding dielectric layers and the bonded first and second bonding pads.

14. The structure of claim 13, wherein the third bonding structure includes a third bonding dielectric layer and third bonding pads embedded therein, and a second bonding interface is located between the bonded first and third bonding dielectric layers and the bonded first and third bonding pads.

15. The structure of claim 10, further comprising a fourth bonding structure disposed on the first bonding structure and located between the first bonding structure and the second die and the second encapsulant, and a bonding interface is located between the first bonding structure and the fourth bonding structure.

16. A method, comprising:
forming a first bonding structure with electrically floating marks;
providing first dies, each first die having a second bonding structure;
disposing the first dies and aligning the first dies over a first side of the first bonding structure using the electrically floating marks as alignment marks;
bonding the first dies with the first bonding structure, each second bonding structure is bonded with the first bonding structure;
forming a first encapsulation material over the first dies and covering the first die to form a first wafer structure;
providing second dies, each second die having a third bonding structure;
disposing the second dies and aligning the second dies over a second side of the first bonding structure opposite to the first side using the electrically floating marks as the alignment marks;
bonding the second dies with the first bonding structure, each third bonding structure is bonded with the first bonding structure; and
forming a second encapsulation material over the second dies and at least laterally wrapping around the second dies to form a second wafer structure.

17. The method of claim 16, wherein each second die includes through die vias, and the method further comprises performing a thinning down process to partially removing a portion of each second die until the through die vias are exposed.

18. The method of claim 17, further comprising forming a redistribution layer over the second wafer structure, and the redistribution layer is electrically connected with the second dies by the through dies vias.

19. The method of claim 16, further comprising performing a dicing process to dice the first and second wafer structures to form individual stacking structures, wherein the dicing process cuts through the first and second encapsulation materials and the first bonding structure without cutting the electrically floating marks.

20. The method of claim 16, further comprising forming a fourth bonding structure before bonding the second dies, and the second dies are bonded to the fourth bonding structure.
